(19) United States
(12) Patent Application Publication
(10) Pub. No.: US 2020/0355753 A1
(43) Pub. Date: Nov. 12, 2020

(54) ELECTROLYTE MEASURING DEVICE AND METHOD OF DISCRIMINATING CONNECTION STATE OF ELECTRODE UNIT OF ELECTROLYTE MEASURING DEVICE

(71) Applicant: A&T CORPORATION, Fujisawa-shi (JP)

(72) Inventors: Hiroaki KANNO, Machida-Shi (JP); Shinya KONPARU, Fujisawa-shi (JP); Akira TAKIGUCHI, Shimoina-gun (JP); Seiichi MIZUKOSHI, Chigasaki-shi (JP)

(73) Assignee: A&T CORPORATION, Fujisawa-shi (JP)

(21) Appl. No.: 16/938,306

(22) Filed: Jul. 24, 2020

Related U.S. Application Data
(63) Continuation of application No. PCT/JP2019/002589, filed on Jan. 25, 2019.

(30) Foreign Application Priority Data
Jan. 26, 2018 (JP) 2018-011754

(51) Int. Cl. G01R 31/67; G01R 29/12; G01N 27/333

(52) U.S. Cl. CPC G01R 31/67; G01N 27/333; G01R 29/12

(57) ABSTRACT

An electrolyte measuring device includes an electrode unit including at least one detachable ion selective electrode and a detachable reference electrode; a signal input circuit for receiving electric potential from the electrode unit; a differential amplifier circuit that amplifies a difference between output from the ion selective electrode and the reference electrode; a signal processing circuit that calculates ion concentration using a signal from the differential amplifier circuit; a direct current power source that applies direct current voltage exceeding an electromotive force of the ion selective electrode to the electrode unit; and a wiring unit connecting the signal input circuit and the signal processing circuit. The signal processing circuit discriminates a connection state of each ion selective electrode to the device, based on the electric potential when a signal of the signal input circuit via the wiring unit is measured after application of the direct current voltage to the electrode unit.

### CROSS REFERENCE TO RELATED APPLICATIONS

This is a continuation application of International Application PCT/JP2019/002589 filed on Jan. 25, 2019 which claims priority from a Japanese Patent Application No. 2018-011754 filed on Jan. 26, 2018 the contents of which are incorporated herein by reference.

### BACKGROUND OF THE INVENTION

### 1. Field of the Invention

Embodiments of the invention relate to an electrolyte measurement technology and a method of discriminating a connection state of an electrode unit of an electrolyte measuring device.

### 2. Description of Related Art

Conventionally, a known electrolyte measuring device that uses an ion selective electrode is a device that measures electrolyte ion concentration of, for example, urine or serum. Such a device uses an ion selective electrode and a reference electrode to measure electromotive force of a sample solution generated by diluting a specimen with a diluent and uses the electromotive force of a standard solution for comparison. Further, based on respective measurement data for the sample solution and the standard solution, electrolyte ion concentration of a measured component contained in the sample solution is measured.

FIG. 4 is a diagram depicting a configuration of a general conventional electrolyte measuring device. The electrolyte measuring device is configured by an ion selective electrode unit 41 that is a measuring unit, a specimen supplying unit 42 that pretreats and supplies a specimen to the electrode unit, a dilution vessel 43, a diluent supplying unit 44, a standard solution supplying unit 45, a pump unit 46, a signal input circuit 47 that measures the electromotive force of the electrode unit, a differential amplifier circuit 48, and a signal processing circuit 49.

In the electrode unit 41, ion selective electrodes for, for example, sodium (Na), potassium (K), and chloride (CI) and a reference electrode (Ref) are disposed.

FIG. 5 is a diagram depicting an example of a structure of the ion selective electrode of the electrolyte measuring device. An ion sensitive film 151 adhered on a support body 152 of the ion selective electrode is in contact with a flow channel 156 and a sample solution passing through a hole (dotted-lined part in drawing) in the support body 152. The support body 152 is held between case members 153, 154, an internal void is filled with an internal liquid such as a potassium chloride aqueous solution, and a local battery is formed by a silver/silver chloride electrode 155 inserted in the void. A part of an outer side of the case member of the silver/silver chloride electrode 155 is connected to the electrolyte measuring device through, for example, a detachable connection plug (for example, refer to Japanese Laid-Open Patent Publication No. 2016-180630).

A sample solution prepared in the dilution vessel 43 depicted in FIG. 4 is introduced to the electrodes and electric potential generated from the electrodes is measured. The electric potential generated by the electrodes is converted to a potential difference by the differential amplifier circuit 48 based on the reference electrode after introduction to the signal input circuit 47, is sent the signal processing circuit 49 and is compared to a standard solution concentration, whereby respective ion concentrations in the sample solution are calculated.

As a conventional electrolyte measuring device, a technology that discriminates a measuring electrode and a calibration electrode (for example, refer to Japanese Laid-Open Patent Publication No. 2002-257782), a technology that detects a malfunction such as dropping of or disconnection of an electrode connector, or degradation of an electrode (for example, refer to Japanese Laid-Open Patent Publication No. 2016-218067), and a technology that prevents degradation of characteristics of the ion selective electrode (for example, refer to Japanese Laid-Open Patent Publication No. 2016-180630) have been disclosed.

### SUMMARY OF THE INVENTION

According to an embodiment of the invention, an electrolyte measuring device includes an electrode unit including one or more ion selective electrodes attachable to and detachable from the device and a reference electrode attachable to and detachable from the device; a signal input circuit for receiving an electric potential from the electrode unit; a differential amplifier circuit that amplifies a difference between output of the one or more ion selective electrodes and output of the reference electrode; a signal processing circuit that calculates an ion concentration using a signal output from the differential amplifier circuit; a direct current power source that applies a direct current voltage exceeding an electromotive force of the one or more ion selective electrodes to the electrode unit; and a wiring unit that connects the signal input circuit and the signal processing circuit. The signal processing circuit, individually for each of the one or more ion selective electrodes of the electrode unit, determines a connection state with respect to the device, based on the electric potential when a signal of the signal input circuit via the wiring unit is measured after application of the direct current voltage to the electrode unit.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1A is a circuit diagram of an electrolyte measuring device according to a first embodiment of the present invention.

FIG. 1B is a diagram depicting an example of a structure of an ion selective electrode of the electrolyte measuring device.

FIG. 2 is a circuit diagram depicting a signal input circuit of the electrolyte measuring device of the first embodiment in detail.

FIG. 3 is a circuit diagram of an electrolyte measuring device according to a second embodiment of the present invention.

FIG. 4 is a diagram depicting a configuration of a general conventional electrolyte measuring device.

FIG. 5 is a diagram depicting an example of a structure of an ion selective electrode of the conventional electrolyte measuring device.

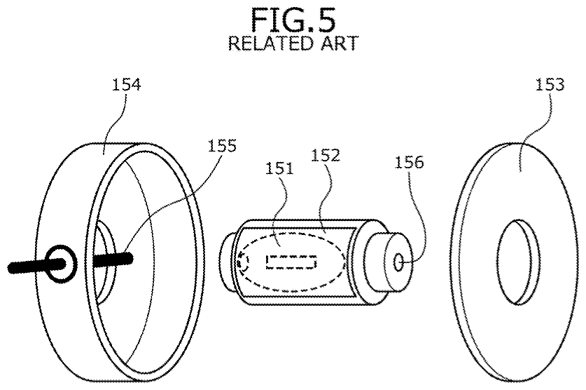

### DETAILED DESCRIPTION OF THE INVENTION

Referring to the accompanying drawings, exemplary embodiments according to the present invention are explained in detail below.

First, problems associated with the conventional techniques will be discussed. In the conventional techniques, a problem arises in that checking no malfunction in an electrolyte measuring device is so hard to confirm.

Conventionally, in a general electrolyte measuring device, multiple ion selective electrodes are installed in a manner enabling attaching and detaching with respect to the electrolyte measuring device. In this case, there is a possibility that proper measurement cannot be performed due to an individual electrode being forgotten to be connected, a connection failure or a disconnection of an electrode. Nonetheless, even when an electrode cable or a liquid ground cable has a connection failure, is disconnected or dropped, the measured value is at a same level equivalent to a proper measurement of a sample solution and therefore, it is difficult to discern whether the measurement was performed correctly.

For these reasons, in the technique recited in Japanese Laid-Open Patent Publication No. 2002-257782, a dedicated detection device such as a detection sensor or an electrode insertion switch is provided separately to determine the electrical connection state of each electrode. However, with this method, there is a disadvantage in that the complexity of the device increases since modification to add an electrical structure such as newly providing a detection circuit in a measurement circuit is necessary.

Further, the technique recited in Japanese Laid-Open Patent Publication No. 2016-218067 needs to perform a check measurement same as actual measurement according to the procedure using the diluent and the standard solution. Further, there is a technical disadvantage of an inability to check a connection failure, disconnection, or dropping of the electrode cable of the reference electrode.

### First Embodiment

An electrolyte measuring device and a method of checking the connection state of an electrode unit of an electrolyte measuring device according to a first embodiment of the present invention will be described in detail.

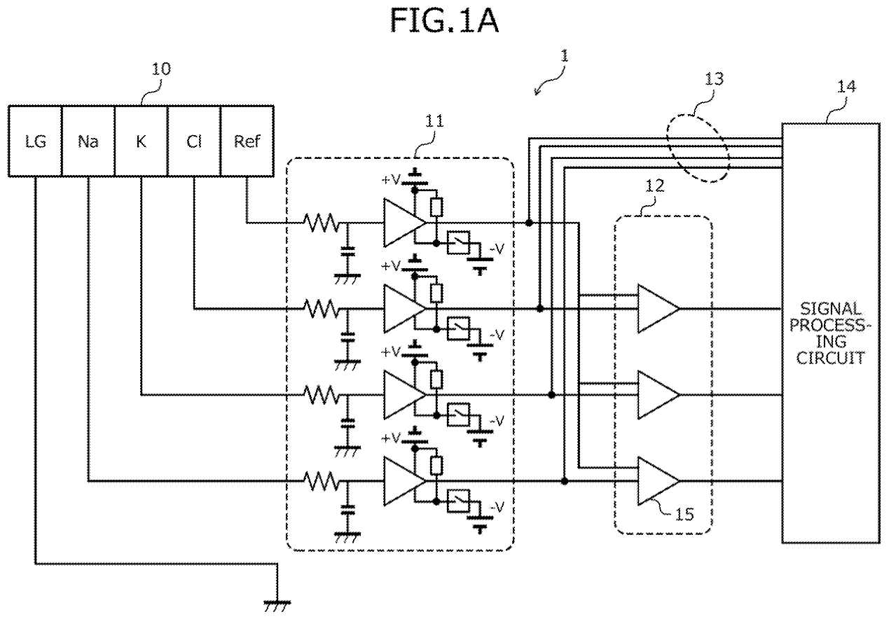

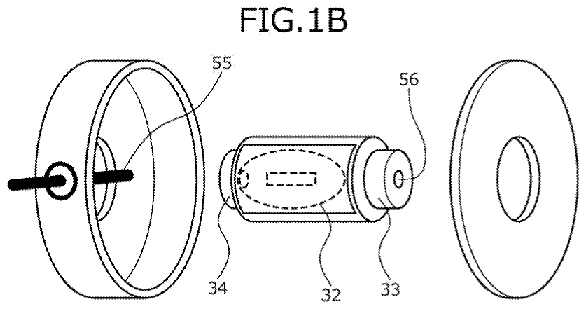

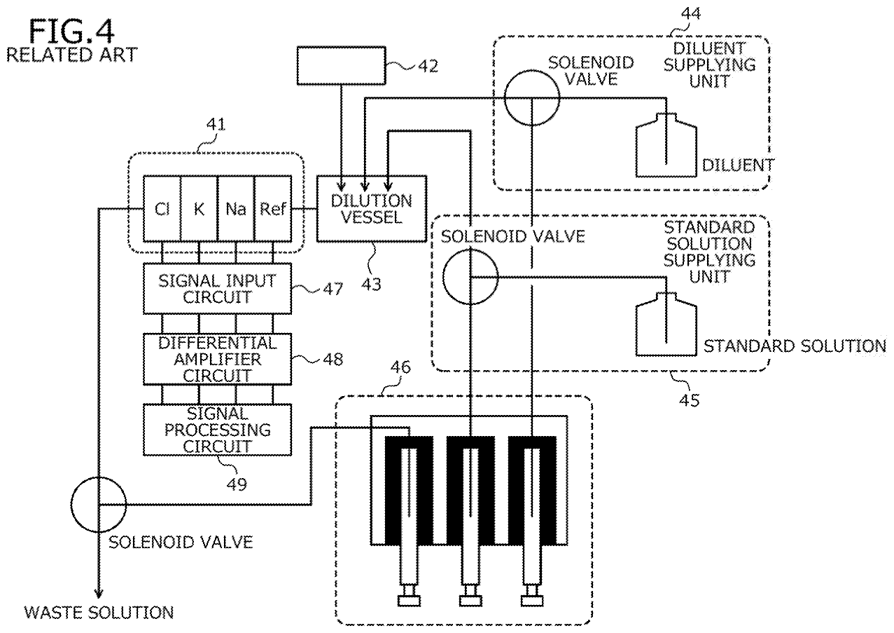

FIG. 1A is a circuit diagram of an electrolyte measuring device according to a first embodiment of the present invention. FIG. 1A depicts mainly a configuration related to determination and connection check of an electrode unit 10 in an overall configuration of an electrolyte measuring device 1. Other components (a specimen supplying unit, a dilution vessel, a diluent supplying unit, a standard solution supplying unit, a pump unit, etc.) of the electrolyte measuring device 1 are configured similarly to the components depicted in FIG. 4 and description thereof is omitted hereinafter. FIG. 1B is a diagram depicting an example of a structure of the ion selective electrode of the electrolyte measuring device.

The electrode unit 10 is connected to a signal input circuit 11, and output of the signal input circuit 11 is output to a signal processing circuit 14 through a differential amplifier 12.

In the electrode unit 10, electrodes including a sodium ion selective electrode (Na), a potassium ion selective electrode (K), a chloride ion selective electrode (CI), a reference electrode (Ref), and a liquid ground electrode (LG) are disposed side by side so that their flow channel 56 of the electrodes depicted in FIG. 1B become a straight line. In the electrolyte measuring device 1, the ion selective electrodes and the reference electrode of the electrode unit 10 are mounted enabling attachment and detachment thereof to and from wiring of the main body of the device.

Here, the liquid ground electrode (LG) of the electrode unit 10 is provided to ground electric potential of a sample solution introduced into the flow channel and has a function of reducing measurement system noise. Resistance between the ground and a terminal part of each silver/silver chloride electrode 55 of the ion selective electrodes is about a few hundred kilo-ohms (kΩ) in a state when the flow channel 56 is filled with a sample solution, and the ion selective electrodes are filled with an internal liquid.

In the electrolyte measuring device 1 of the present invention, before actual specimen measurement operations, the operations described below for checking the connection states of individual electrodes (the sodium ion selective electrode (Na), the potassium ion selective electrode (K), the chloride ion selective electrode (Cl), the reference electrode (Ref), the liquid ground electrode (LG)) are performed. Electric potential from each of the electrodes of the electrode unit 10 is introduced into the signal input circuit 11 from each of the respective silver/silver chloride electrodes 55 (refer to FIG. 1B) through a connector such as a plug.

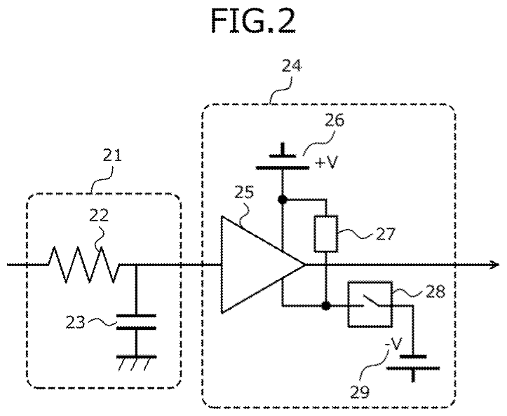

FIG. 2 is a circuit diagram depicting the signal input circuit of the electrolyte measuring device of the first embodiment in detail. A circuit that is provided in each of the electrodes of the electrode unit 10 is depicted. In the description hereinafter, circuit configuration is common to each of the ion selective electrodes and therefore, a principle of the present invention will be described in detail for a configuration of the reference electrode and the configuration of one of the ion selective electrodes.

The signal input circuit 11 is configured by rectifier circuit units 21 and receiving units 24. Each of the rectifier circuit units 21 is formed by a resistor 22 connected in series to a signal, and a capacitor 23 connected in parallel and having one end grounded. For example, in the rectifier circuit unit 21, a 1-megaohm (MΩ) metal film element is used as the resistor 22, and a 0.01-microfarad (μF) film capacitor is used as the capacitor 23. Signals from the electrodes are sent to the receiving units 24, respectively, after being respectively introduced into the rectifier circuit units 21 and having noise removed. At the receiving units 24, the signals are amplified by operational amplifiers 25 and output to the subsequent differential amplifier 12.

Each of the receiving units 24 is formed by one of the operational amplifiers 25, a positive direct current power source 26, a negative direct current power source 29, a high resistance element 27, and a switch 28. The positive direct current power source 26 and through the switch 28, the negative direct current power source 29 are connected to the operational amplifier 25 of the receiving unit 24, with positive and negative voltage of five volts being respectively applied by each. The high resistance element 27 uses a resistance element of about 10 kilo-ohm (kΩ) to prevent electrical shorts between the positive and the negative direct current power sources.

Output of the operational amplifier 25 is split into two branches (refer to FIG. 1A, FIG. 2). A first branch of the output of the operational amplifier 25 is further sent to the signal processing circuit 14 through a wiring unit 13 and is used as a signal for determining connection-error of a plug of the present invention. A second branch of the output of the operational amplifier 25 is sent to a differential amplifier circuit 15 of the differential amplifier 12, each differential amplifier circuit 15 amplifies and inputs to the signal processing circuit 14, a differential signal between a signal from a corresponding ion selective electrode and a signal from the reference electrode (Ref). The signal processing circuit 14 calculates an electrolyte ion concentration from a magnitude of the differential signal of a sample solution of an unknown concentration and a standard solution of a known concentration.

A measurement sequence by the electrolyte measuring device described above will be described. In the description, in particular, a process of detecting a connection failure of the electrode unit 10 will be described. First, a diluent is sent to the electrode unit 10, filling the flow channel 56.

Thereafter, to detect of a connection failure of the electrode unit 10 (connection check mode), the switches 28 of the receiving units 24 in the signal input circuit 11 are set to OFF (interrupt) and the negative direct current power source applied to the operational amplifiers 25 is cut off.

As a result, a circuit is formed in that the positive direct current power source of the operational amplifiers 25 is grounded through the rectifier circuit unit 21 and the flow channel 56 of electrode unit, and positive voltage (+5 volts) charges the capacitors 23. This voltage corresponds to significantly higher electric potential compared to the electromotive force induced by the ion selective electrodes of the electrode unit such as, for example, the maximum electromotive force of the Na ion selective electrode. Under these circuit conditions, the OFF period of the switches 28 is a charging period of the capacitors. A charging completion time for the capacitors 23 suffices to be about 0.5 seconds and thereafter, the switches 28 are shorted again, the charging of the capacitors 23 is ended, and the electrolyte measuring device returns to the normal measuring mode.

In this state, when the plugs, etc. of the electrode unit are connected properly, residual charge of the capacitors 23 is discharged through the electrode unit 10. Electric discharge time constants of the capacitors 23 at this time are largely determined by the resistors 22, the resistance between the ground and the terminal part of the silver/silver chloride electrode 55 of each of the ion selective electrodes of the electrode unit 10, and the capacitance of the capacitors 23.

Here, when the plug, etc. of the electrode unit 10 is actually connected properly, discharge is based on the electric discharge time constants described above. However, when there is a failure in a connection of the electrode unit 10 such as a disconnection, the charge of the capacitors 23 is discharged based on internal resistance of the operational amplifiers 25 and therefore, the rate of decay of the residual electric potential is remarkable slower compared to proper connection.

Thus, the switches 28 are returned to ON, negative direct current voltage is applied to the operational amplifiers 25 and the state of the electrolyte measuring device is returned to a normal measuring state in which electric potential occurring in the signal input circuit 11 is measured by the signal processing circuit 14 through the wiring unit 13. The electric potential measured at this time is electric potential due to residual charge in the capacitors 23. When each of the ion selective electrodes is properly connected, substantially zero volts are indicated.

However, in a case of a failure such as an unplugged plug, when the electric potential shows a value higher than a predetermined specified value (for example, 3 volts) set as a threshold corresponding to the positive voltage (+5 volts) above, it may be determined that charge from the capacitors 23 was not discharged through the electrode unit 10 and thus, it may be determined that there is a failure in the connection of the electrode unit 10.

Here, the signal processing circuit 14 outputs notification of the failure to an external device, whereby notification of the failure in the connection of the electrode unit 10 may be given to a user, etc. by display or sound.

Further, when the signals of the ion selective electrodes show high values all together, connection failure or disconnection of the liquid ground (LG) cable may be suspected and the signal processing circuit 14 may give notification indicating a connection failure of the liquid ground (LG) cable.

After the measurement described above, to minimize the risk of an application of excessive external voltage to the electrode unit 10, the switches 28 may be swiftly returned to the original state, returning to the normal measuring mode.

Further, a non-depicted control unit or the like provided in the electrolyte measuring device 1 may be configured to perform switching control of the switches 28 to switch to the connection check mode of the electrode unit 10 before the start of the normal measuring mode, and automatically executing the connection check mode with a predetermined amount of time.

### Second Embodiment

An electrolyte measuring device and a method of discriminating the connection state of electrode unit of an electrolyte measuring device according to a second embodiment of the present invention will be described in detail.

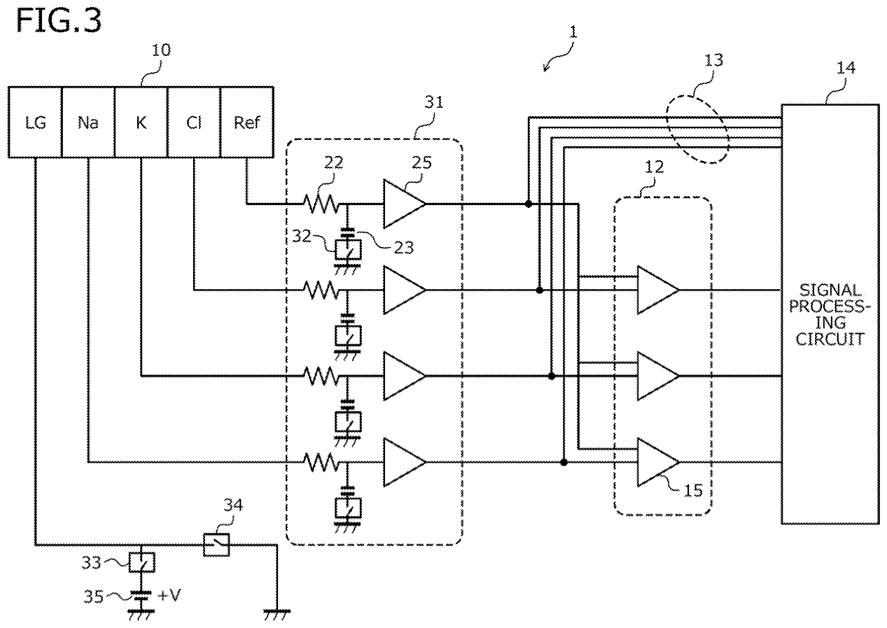

FIG. 3 is a circuit diagram of the electrolyte measuring device according to the second embodiment of the present invention. In the electrolyte measuring device 1 depicted in FIG. 3, components similar to those of the first embodiment (FIGS. 1A, 1B, 2) are given the same reference numerals used in the first embodiment. Further, in the second embodiment as well, the operations described below for determining the connection states of individual electrodes before actual specimen measurement operations are similar to those of the first embodiment.

On the circuit, unlike in the first embodiment, configuration is such that switches 33, 34 are provided between the electrode unit 10 and the ground, and switching can be possible between a positive direct current power source 35 and the ground. Further, the switches 28 of the receiving unit 24 of the first embodiment (FIG. 2) are eliminated and instead, switches 32 are disposed between the ground and the capacitors 23 of the rectifier circuit unit 21. Further, positive electric potential (+4 volts) significantly higher than the electromotive force of the ion selective electrodes is used for the positive direct current power source 35.

In the example depicted in FIG. 3, between the liquid ground electrode (LG) of the electrode unit 10 and the ground, the switches 33, 34 are provided connected in parallel and serially. The switch 33 is grounded through the positive direct current power source 35.

A measurement sequence will be described. First, diluent is sent to the electrode unit, filling the flow channel 56 of the electrode unit 10. Thereafter, the switches 32 in a signal input circuit 31 are set to OFF, cutting off the capacitors 23 and the ground. Simultaneously, the switch 34 connected to the electrode unit 10 is set to OFF, disconnecting the connection with the ground. Thereafter, the switch 33 is set to ON, thereby connecting the positive direct current power source 35.

Under this circuit state, voltage (+4 volts) of a direct current power source 35 is divided by resistance near the electrode unit 10 and the resistance of the resistors 22, and under a condition of the second embodiment, is applied mostly to the resistors 22. Therefore, the voltage of the positive direct current power source 35 applied to the electrode units reaches the signal input circuit 31 through the electrode unit 10, passes through the wiring unit 13 as output of the operational amplifiers 25 and is measured by the signal processing circuit 14.

Therefore, when a measurement result of the signal processing circuit 14 is at least a predetermined specified value (for example, about +3 volts) set as a threshold corresponding to the voltage (+4 volts) of the direct current power source 35, it is possible to judge that connection of the electrode unit 10 is proper. Conversely, when a measurement result of the signal processing circuit 14 is less than the specified value, it may be judged that the circuit from the positive direct current power source 35 to the signal processing circuit 14 is not formed and it is possible to judge that the connection state of the electrode unit 10 has any malfunction.

After the measurement described above, to minimize the risk of an application of excessive external voltage to the electrode unit 10, the switches 32, 33, 34 have to be swiftly returned to the original state, returning to the normal measuring mode. Setting the switches 32 to OFF to cut off the capacitors 23 from the ground is an operation performed to suppress current flowing through the electrode unit 10 by applying the voltage (+4 volts) of the direct current power source 35.

According to the embodiments described above, the electrolyte measuring device may provide notification of detection of a malfunction in the connection state of the electrodes of the electrode unit such as disconnection or dropping of a plug of the ion selective electrodes, the reference electrode, or the liquid ground electrode, without addition of a dedicated detection device.

Further, actual measurement using a standard solution having a known ion concentration value is not needed. Moreover, before the start of actual measurement by the electrolyte measuring device, the connection state may be checked easily and therefore, after confirmation of the connection state, it becomes possible to perform specimen measurement in a proper state at all times.

Further, residual electric potential of each of the electrodes of the electrode unit is detected and therefore, the connection state may be confirmed effectively not just for the ion selective electrodes but for the reference electrode as well and this point is one feature that the conventional techniques cannot provide. Further, the first and the second embodiments have a feature of easy performing in that it is needless to use of a standard solution having a known ion concentration value.

Thus, according to the embodiments described above, malfunctions in the connection state of the electrode unit such as the disconnection or dropping of the liquid ground cable or the electrode cable of the ion selective electrodes, and/or the reference electrode can be checked without the addition of a dedicated detection device. Further, performing actual measurement using a standard solution for which the ion concentration is known is unnecessary. Moreover, confirmation may be performed easily before the start of actual measurement and therefore, it becomes possible to perform specimen measurement in a proper state thereafter at all times.

Further, according to the embodiments described above, extra sensors for monitoring the connection states of the electrodes are unnecessary, retrofitting an existing electrolyte measuring device is easy, and low-cost improvement of the performance of the device becomes possible.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. An electrolyte measuring device, comprising:
an electrode unit including one or more ion selective electrodes attachable to and detachable from the device and a reference electrode attachable to and detachable from the device;
a signal input circuit for receiving an electric potential from the electrode unit;
a differential amplifier circuit that amplifies a difference between output of the one or more ion selective electrodes and output of the reference electrode;
a signal processing circuit that calculates an ion concentration using a signal output from the differential amplifier circuit;
a direct current power source that applies a direct current voltage exceeding an electromotive force of the one or more ion selective electrodes to the electrode unit; and
a wiring unit that connects the signal input circuit and the signal processing circuit, wherein
the signal processing circuit, individually for each of the one or more ion selective electrodes of the electrode unit, discriminates a connection state with respect to the device, based on the electric potential when a signal of the signal input circuit via the wiring unit is measured after application of the direct current voltage to the electrode unit.

2. The electrolyte measuring device according to claim 1, wherein
the electrode unit has a first end that is grounded and a second end that is connected to the signal input circuit,
the device further comprises a capacitor having a first end connected to a part of the signal input circuit near the electrode unit and a second end that is grounded, and
the signal processing circuit, individually for each of the one or more ion selective electrodes, discriminates the connection state by measuring a residual electric potential of the capacitor after completion of charging of the capacitor by the direct current power source.

3. The electrolyte measuring device according to claim 2, wherein
the direct current power source is a power source for an operational amplifier disposed in the signal input circuit.

4. The electrolyte measuring device according to claim 1, wherein
the direct current power source and a ground are disposed to be selectively connected to a first end of the electrode unit via a switch,
a rectifier circuit unit of the signal input circuit is disposed at a second end of the electrode unit and a capacitor of the rectifier circuit unit is grounded via a switch, and
the signal processing circuit, individually for each of the one or more ion selective electrodes, discriminates the connection state by measuring a voltage induced in the electrode unit by an application of the direct current voltage to the electrode unit by the direct current power source when the capacitor is not grounded.

5. The electrolyte measuring device according to claim 1, wherein
the electrode unit includes a liquid ground electrode disposed therein.

6. A method of discriminating a connection state of an electrode unit of an electrolyte measuring device having an electrode unit including one or more ion selective electrodes attachable to and detachable from the device and a reference electrode attachable to and detachable from the device, a signal input circuit for receiving an electric potential from the electrode unit, a differential amplifier circuit that amplifies a difference between output of the one or more ion selective electrodes and output of the reference electrode, a signal processing circuit that calculates an ion concentration using a signal output from the differential amplifier circuit, a direct current power source that applies a direct current voltage exceeding an electromotive force of the one or more ion selective electrodes to the electrode unit, and a wiring unit that connects the signal input circuit and the signal processing circuit, the method comprising:
applying the direct current to the electrode unit;
measuring a signal of the signal input circuit via the wiring unit by the signal processing circuit; and
determining the connection state individually for the one or more ion selective electrodes with respect to the device by the signal processing circuit.
